(19) United States
(12) Patent Application Publication
(10) Pub. No.: US 2025/0300599 A1
(43) Pub. Date: Sep. 25, 2025

(54) COVER PLATE AND SOLAR CELL MODULE INCLUDING THE SAME

(71) Applicants: Hyundai Motor Company, Seoul (KR); Kia Corporation, Seoul (KR); University-Industry Cooperation Group of Kyung Hee University, Yongin (KR)

(72) Inventors: Byung Hong Lee, Hwaseong (KR); Min Jae Lee, Hwaseong (KR); Ri Ra Kang, Hwaseong (KR); Sun Kyung Kim, Suwon (KR); Jae Hyun Kim, Suwon (KR)

(21) Appl. No.: 18/933,276

(22) Filed: Oct. 31, 2024

(30) Foreign Application Priority Data
Mar. 25, 2024 (KR) 10-2024-0040476

(51) Int. Cl. H02S 40/22; H02S 20/22

(52) U.S. Cl. CPC H02S 40/22; H02S 20/22

(57) ABSTRACT

A solar cell module includes a solar cell and a cover plate designed to enhance solar energy absorption. The cover plate features an optical pattern part composed of a plurality of irregularities with an asymmetrical shape relative to a first direction perpendicular to the solar cell. These irregularities have triangular cross-sections with differing first and second angles, configured to reduce sunlight reflection at high incident angles by directing light towards the solar cell. The cover plate may include a base part with the optical pattern part protruding from it, and the irregularities can be arranged to form a continuous pattern. Additionally, a coating layer with a refractive index lower than that of the cover plate material is applied to the surface of the irregularities, further improving light absorption.

### CROSS-REFERENCE TO RELATED APPLICATION

This application claims under 35 U.S.C. § 119(a) the benefit of Korean Patent Application No. 10-2024-0040476, filed in the Korean Intellectual Property Office on Mar. 25, 2024, the entire contents of which are incorporated herein by reference.

### BACKGROUND

### Technical Field

The present disclosure relates to a cover plate designed to optimize solar energy absorption and a solar cell module including the same thereby significantly enhancing the overall efficiency and performance of solar power generation systems.

### Background

To achieve the greenhouse gas reduction goal according to the carbon neutralization declaration, zero-energy buildings become mandatory, and vehicle greenhouse gas management systems are implemented. Accordingly, environment-friendly energy is actively developed and applied.

In the case of solar power generation, a solar cell may be installed in a city without noise, vibration, and exhaust gases, and energy costs may be reduced through direct coupling with an energy-consuming device that consumes direct current (DC). Thus, the solar cell is spotlighted as a distributed power source, and thus many efforts are conducted to increase a power generation amount through solar power.

In addition to improving efficiency of the solar cell itself and increasing an application area of the solar cell to increase power generation efficiency, effects are made to apply a roof-type solar cell, a side-type facade-type solar cell, and a spandrel panel-type solar cell through adjusting of an installation angle of the solar cell, to increase the application area.

In particular, in the case of a building integrated photovoltaic (BIPV) or a solar cell module for a vehicle door, sunlight is input to a side surface, and thus a solar cell module that may suppress reflection preventing at a large incident angle and improve efficiency of solar absorption is required.

The above-described background art, which is possessed or acquired by an inventor in a process of deriving the present disclosure, is not necessarily a known technology disclosed to the general public before the present disclosure is filed.

### SUMMARY

The present disclosure has been made to solve the above-mentioned problems occurring in the prior art while advantages achieved by the prior art are maintained intact.

An aspect of the present disclosure provides a solar cell module that may increase efficiency of solar power generation by controlling an optical path of the irradiated sunlight.

Another aspect of the present disclosure provides a solar cell module that may reduce reflectance of the sunlight and improve an absorption rate of the sunlight.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, there is provided a solar cell module including a solar cell that absorbs the sunlight, and a cover plate that covers the solar cell, wherein an optical pattern part having a plurality of irregularities having an asymmetrical shape with respect to a first direction perpendicular to the solar cell is formed in the cover plate.

The cover plate may include a base part that covers the solar cell, the optical pattern part may protrude from the base part, and the base part and the optical pattern part may be integrally formed.

The solar cell may be positioned on one surface of the base part, and the optical pattern part may be formed on the other surface opposite to the one surface of the base part.

Each of the irregularities may include a first surface extending from the base part and a second surface extending from the base part such that the second surface is connected to the first surface, and a measure of a first angle formed between the first surface and the base part and a measure of a second angle formed between the second surface of the base part may be different from each other.

The measure of the first angle may be greater than the measure of the second angle.

Each of the plurality of irregularities may have a shape extending in a second direction perpendicular to the first direction.

A cross section of the irregularities, which is perpendicular to the second direction, may have a triangular shape.

The plurality of irregularities may be continuously arranged in a third direction intersecting the first direction and the second direction.

The plurality of irregularities may be spaced a predetermined distance from each other in the third direction.

Among two adjacent irregularities, the first surface of one irregularity and the second surface of the other one irregularity may be connected to each other.

The plurality of irregularities may be continuously arranged in the second direction and the third direction.

The cover plate may be formed of a glass material or a polymer material.

The solar cell module may further include a coating layer provided in the irregularity to prevent reflection of the sunlight.

The solar cell module may further include a glass plate stacked between the solar cell and the cover plate, wherein the cover plate may be formed of a polymer material.

The second surface may be recessed toward the cover plate.

The irregularities may have a symmetrical shape with respect to a plane formed parallel to the first direction.

According to another aspect of the present disclosure, there is provided a cover plate that covers a solar cell, wherein an optical pattern part having a plurality of irregularities having an asymmetrical shape with respect to a first direction perpendicular to an extension direction of the cover plate is formed.

In some embodiments, a solar cell module includes a solar cell configured to absorb sunlight and a cover plate configured to cover the solar cell. The cover plate comprises an optical pattern part with a plurality of irregularities having an asymmetrical shape with respect to a first direction perpendicular to the solar cell. The cover plate may include a base part configured to cover the solar cell, where the optical pattern part may protrude from the base part, and the base part and the optical pattern part may be integrally formed. The solar cell may be positioned on one surface of the base part, and the optical pattern part may be formed on the other surface opposite to the one surface of the base part. Each of the irregularities may include a first surface extending from the base part and a second surface extending from the base part such that the second surface is connected to the first surface. A measure of a first angle formed between the first surface and the base part may be different from a measure of a second angle formed between the second surface and the base part. The measure of the first angle may be greater than the measure of the second angle. The first angle may be about 60 degrees or more and 90 degrees or less, and the second angle may be about 30 degrees or more and 70 degrees or less. Each of the plurality of irregularities may have a shape extending in a second direction perpendicular to the first direction. A cross section of the irregularities, which is perpendicular to the second direction, may have a triangular shape. The plurality of irregularities may be continuously arranged in a third direction intersecting the first direction and the second direction. The plurality of irregularities may be spaced a predetermined distance from each other in the third direction. Among two adjacent irregularities, the first surface of one irregularity and the second surface of the other irregularity may be connected to each other. The plurality of irregularities may be continuously arranged in both the second direction and the third direction.

The cover plate may be formed of a glass material or a polymer material. A coating layer may be provided in the irregularities to prevent reflection of the sunlight. The solar cell module may further include a glass plate stacked between the solar cell and the cover plate, where the cover plate may be formed of a polymer material. In some embodiments, the second surface may be recessed toward the cover plate, and the irregularities may have a symmetrical shape with respect to a plane formed parallel to the first direction. In another embodiment, a cover plate configured to cover a solar cell may include an optical pattern part having a plurality of irregularities with an asymmetrical shape with respect to a first direction perpendicular to an extension direction of the cover plate.

In some embodiments, the solar cell module includes a solar cell and a cover plate configured to cover the solar cell. The cover plate comprises a plurality of irregularities having a triangular cross-sectional shape with asymmetrical angles. These irregularities are configured to reduce reflection of sunlight at high incident angles by directing sunlight toward the solar cell. The first angle of the triangular cross-section may be greater than the second angle, with the first angle being between about 30° and 70° and the second angle being between about 60° and 90°. The irregularities may be arranged such that the first and second surfaces of adjacent irregularities are connected, forming a continuous pattern across the surface of the cover plate. Additionally, a coating layer may be applied on the surface of the irregularities, with the coating layer having a refractive index lower than that of the material of the cover plate.

As discussed, the method and system suitably include use of a controller or processer.

In another embodiment, vehicles are provided that comprise an apparatus as disclosed herein.

### BRIEF DESCRIPTION OF THE DRAWINGS

The above and other objects, features and advantages of the present disclosure will be more apparent from the following detailed description taken in conjunction with the accompanying drawings:

FIG. 1 is a schematic view illustrating an installation state of a solar cell module according to an embodiment of the present disclosure;

FIG. 2 is a perspective view illustrating a shape of a solar cell module according to the embodiment of the present disclosure;

FIG. 3 is a perspective view illustrating the shape of the solar cell module according to the embodiment of the present disclosure, which further includes a glass plate;

FIG. 4 is a side view of the solar cell module when a first angle is a right angle;

FIG. 5 is a side view of the solar cell module when the first angle is smaller than a right angle;

FIG. 6 is a side view of the solar cell module in which a plurality of irregularities are spaced apart from each other;

FIG. 7 is a side view of the solar cell module in which a coating layer is provided on the irregularity;

FIG. 8 is a graph depicting transmittance of the sunlight according to the first angle and a second angle;

FIG. 9 is a perspective view illustrating a shape of a solar cell module according to another embodiment of the present disclosure; and

FIG. 10 is a perspective view illustrating a shape of a solar cell module according to still another embodiment of the present disclosure.

### DETAILED DESCRIPTION

Hereinafter, embodiments of the present disclosure will be described in detail with reference to the accompanying drawings so that those skilled in the art to which the present disclosure pertains may easily implement the present disclosure. The following description is one of several aspects of the embodiments, and in describing an embodiment, detailed descriptions of widely-known functions or configurations will be omitted to make the subject matter of the present disclosure clear.

In the specification, when reference numerals are added to components in respective drawings, the same or similar reference numerals are added to the same or similar components throughout the specification. Components included in one embodiment and components including the common functions will be described using the same names in the other embodiments. Terms or words used in the specification and the appended claims are not limitedly interpreted as usual or dictionary meanings and should be interpreted as meanings and concepts corresponding to the technical spirit of the present disclosure based on the principle that the inventor may appropriately define the concepts of the terms in order to describe his/her invention in the best way.

Further, the present disclosure is not limited to the above-described embodiments, and various modifications and changes may be made from these descriptions by those skilled in the art to which the present disclosure pertains. Therefore, the spirit of the present disclosure should not be limited to the above-described embodiments, and not only the appended claims described below but also all of things equivalent to the appended claims and equivalently modified from the appended claims belong to the scope of the spirit of the present disclosure.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

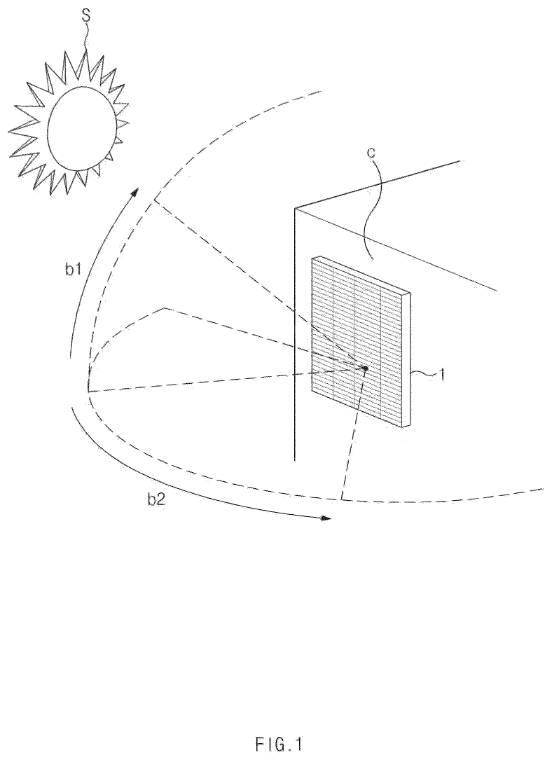

FIG. 1 is a schematic view illustrating an installation state of a solar cell module 1 according to an embodiment of the present disclosure.

Referring to FIG. 1, the solar cell module 1 according to the embodiment of the present disclosure may be installed on a side wall “c” of a building. The solar cell module 1 may have an overall rectangular plate shape and may have a predetermined area and width depending on an area of a required solar cell. When the solar cell module 1 is installed on the side wall “c” of the building in this way, the solar cell module 1 may be placed parallel to the side wall “c” of the building, and thus, the solar cell module 1 may be placed at a predetermined angle with respect to the ground. For example, the solar cell module 1 may be placed perpendicular to the ground. In the case of the side-type solar cell module 1, an input angle of the sunlight into the solar cell module 1 may be changed depending on an elevation angle b1 and an azimuth b2 of the sun, and accordingly, the amount of sunlight absorbed by the solar cell may be changed.

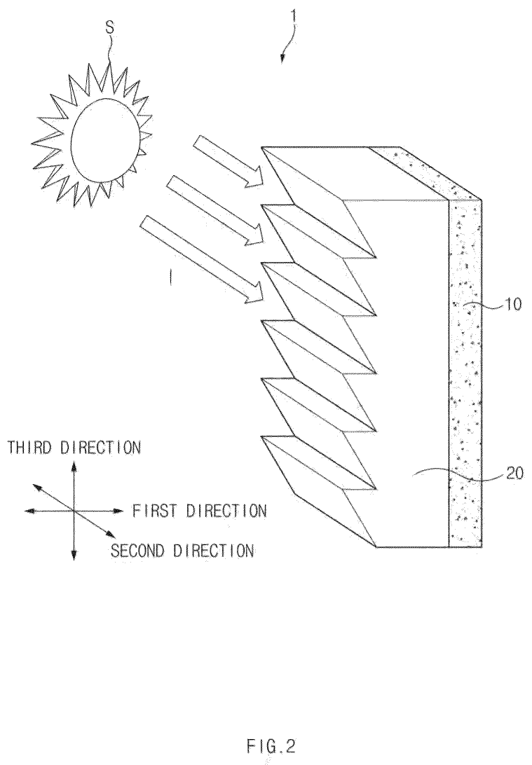

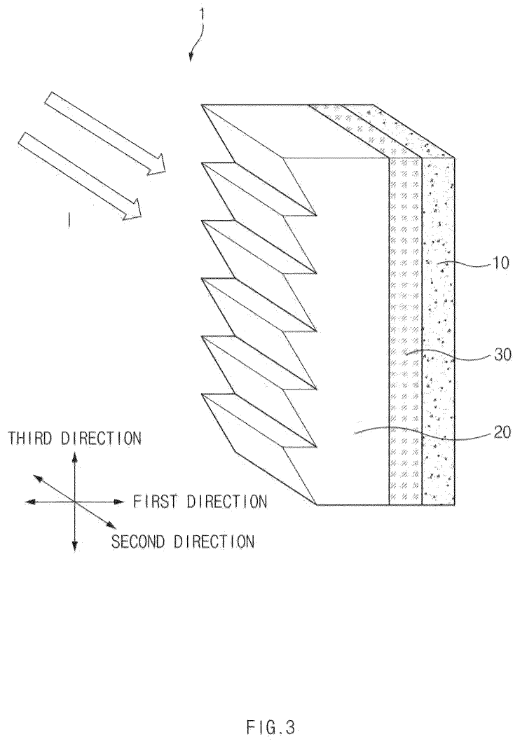

FIGS. 2 and 3 illustrate schematic forms of the solar cell module 1 illustrated in FIG. 1. In detail, FIG. 2 is a perspective view illustrating a shape of the solar cell module 1 according to the embodiment of the present disclosure, and FIG. 3 is a perspective view illustrating the shape of the solar cell module 1 according to the embodiment of the present disclosure, which further includes a glass plate 30.

Referring to FIGS. 2 and 3, the solar cell module 1 may include a solar cell 10 and a cover plate 20.

The solar cell 10 may be provided to absorb the sunlight. The solar cell 10 may be provided in the form of a rectangular plate having a predetermined thickness. The solar cell 10 may be, for example, a silicon solar cell or an inorganic thin film-based non-silicon solar cell, but the present disclosure is not limited thereto. The solar cell 10 may absorb the sunlight and produce electricity using the absorbed sunlight.

The cover plate 20 may be provided to cover the solar cell 10. The cover plate 20 may control an optical path of a sunlight “l” input toward the solar cell module 1. The cover plate 20 may be provided to improve light absorption efficiency of the solar cell module 1 by, for example, suppressing reflection of the input sunlight or changing the input angle of the sunlight into the solar cell 10 by refracting the optical path of the sunlight.

The cover plate 20 may be stacked on the solar cell 10 in a first direction perpendicular to the solar cell 10. One surface of the cover plate 20 may be in contact with and overlap one surface of the solar cell 10.

The cover plate 20 is configured in a flat shape, and an optical pattern part having a plurality of protrusion-shaped irregularities may be formed in a portion of the cover plate 20. The optical pattern part may be formed on a side of the cover plate 20, which is not contact with the solar cell 10. In other words, the solar cell 10 may be positioned on one side of the cover plate 20, and the optical pattern part may be formed on the other side of the cover plate 20, which is opposite to the one side of the cover plate 20. The optical pattern part may be formed in the cover plate 20 in a direction in which the sunlight “l” is irradiated. For example, the optical pattern part may be a prism pattern in which a plurality of irregularities having a triangular pillar shape are arranged in a preset direction.

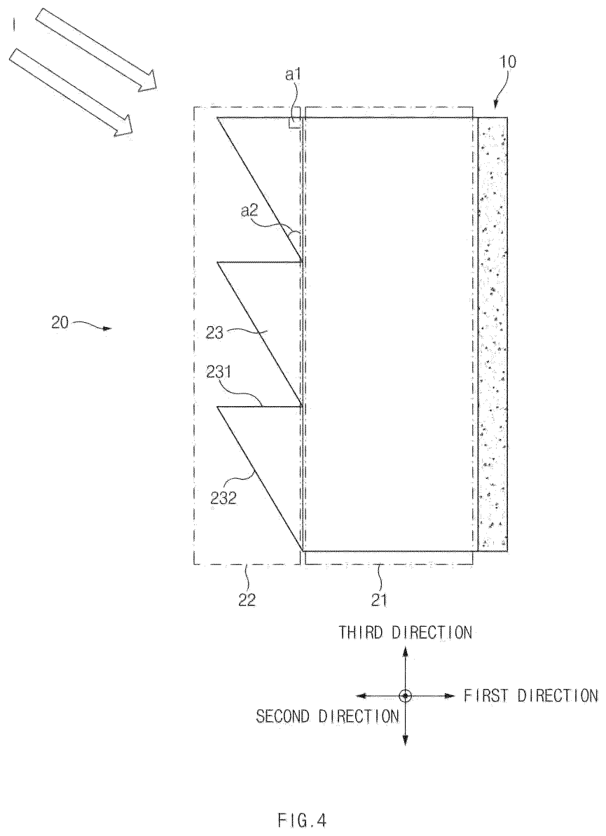

Each of the plurality of irregularities of the optical pattern part may extend in a second direction perpendicular to the first direction. Each of the irregularities may have a bar shape of which a longitudinal direction is the second direction and may be formed in an asymmetric shape in the first direction. The plurality of irregularities may be arranged in a third direction that intersects both the first direction and the second direction. For example, the third direction may be a direction that perpendicularly intersects both the first direction and the second direction. A more detailed form of the optical pattern part and the irregularities provided therein will be described in detail in FIGS. 4 to 7 which will be described below. For example, based on a state in which the solar cell module 1 is mounted on the side wall “c” of the building, the first direction may be a direction perpendicular to the side wall, the second direction may be a horizontal direction extending along the side wall, and the third direction may be a vertical direction.

The cover plate 20 may be formed to have an area and width corresponding to the solar cell 10. The cover plate 20 may be formed of a transparent material having a predetermined rigidity to transmit the sunlight “l.” The cover plate 20 may be formed of, for example, glass or polymer, but the present disclosure is not limited thereto.

An Additional layer may be stacked between the cover plate 20 and the solar cell 10 as needed. For example, the glass plate 30 having a predetermined thickness may be stacked between the cover plate 20 and the solar cell 10. That is, the solar cell 10, the glass plate 30, and the cover plate 20 may be sequentially stacked in the second direction. In this case, the cover plate 20 may be formed of a material different from the glass plate 30. For example, the cover plate 20 may be made of a protective polymer (EVA) material. The glass plate 30, which is a rigid hard cover, may protect the solar cell 10 and support the cover plate 20.

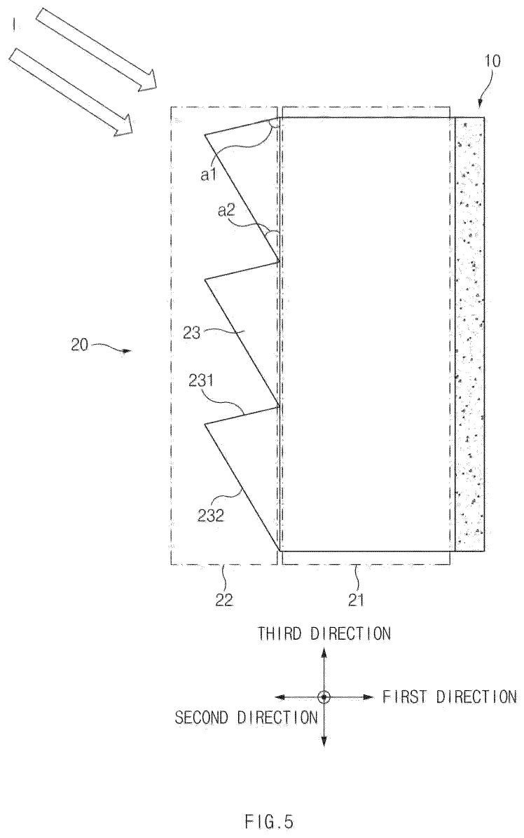

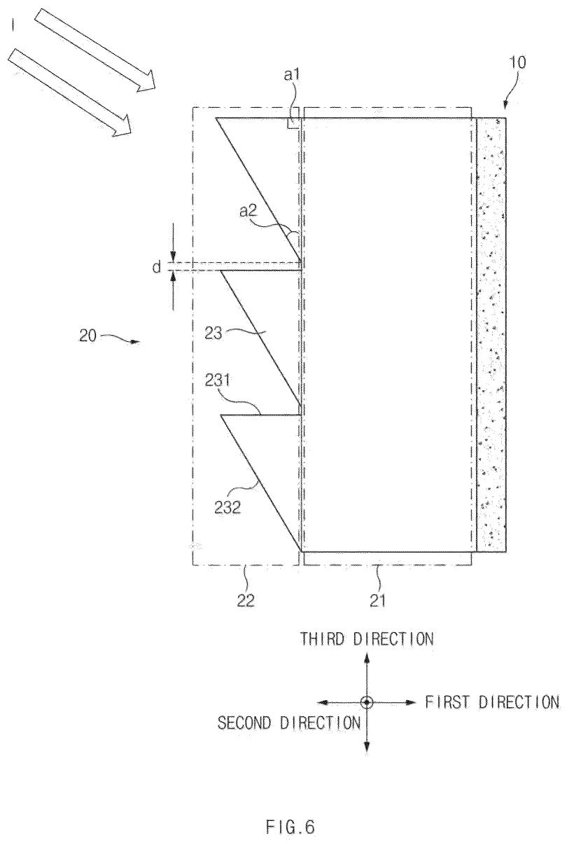

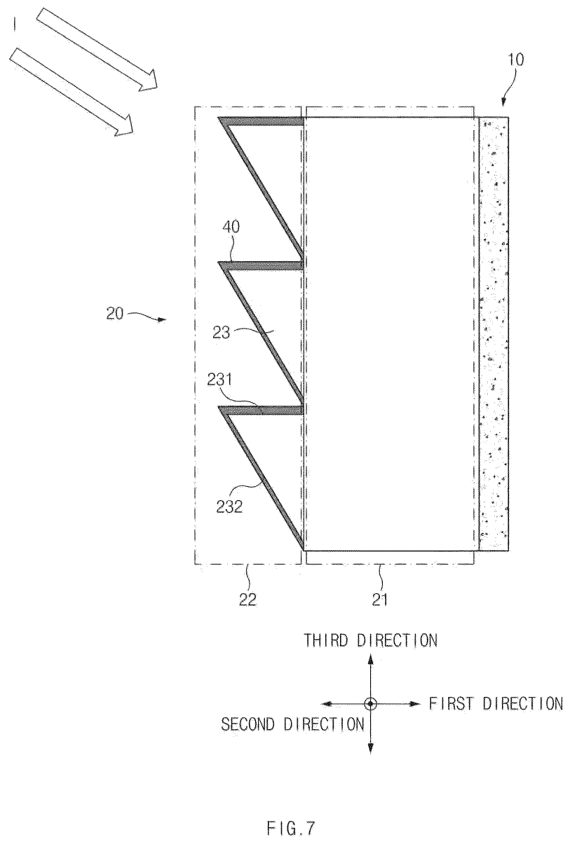

FIGS. 4 to 7 illustrate the solar cell module as viewed from one side in the second direction according to the embodiment of the present disclosure. In detail, FIG. 4 is a side view of the solar cell module when a first angle a1 is a right angle, and FIG. 5 is a side view of the solar cell module when the first angle a1 is smaller than a right angle. FIG. 6 is a side view of the solar cell module in which a plurality of irregularities 23 are spaced apart from each other. FIG. 7 is a side view of the solar cell module in which a coating layer 40 is provided in the irregularity 23.

Referring to FIGS. 4 to 7, the solar cell module according to the embodiment of the present disclosure may include the solar cell 10 and the cover plate 20.

As described above, the cover plate 20 may overlap the solar cell 10 in the first direction perpendicular to the solar cell 10. The cover plate 20 may include a base part 21 and an optical pattern part 22. The base part 21 may be an area that is in contact with and overlaps the solar cell 10. The base part 21 may overlap the solar cell 10 in the first direction. The base part 21 may be provided parallel to the solar cell 10. The base part 21 may be formed in a shape corresponding to the area and width of the solar cell 10 and may have a predetermined thickness in the first direction. The optical pattern part 22 may protrude from the base part 21. The base part 21 and the optical pattern part 22 may be formed integrally. The optical pattern part 22 may protrude from the base part 21 in the first direction. The solar cell 10 may be positioned on one side of the base part 21, and the optical pattern part 22 may be positioned on the other side thereof. The optical pattern part 22 may be formed on the other side of the base part 21 in a direction in which the sunlight “l” is input.

The optical pattern part 22 may include the plurality of irregularities 23. Each of the irregularities 23 may have a shape extending in the second direction perpendicular to the first direction. A cross-sectional shape of each of the irregularities 23, which is perpendicular to a longitudinal direction (second direction), may be a triangular shape. The plurality of irregularities 23 may be arranged in the third direction that intersects the first direction and the second direction.

Each of the irregularities 23 may include a first surface 231 and a second surface 232. The first surface 231 may extend from the base part 21. The first surface 231 may extend at a predetermined angle with the base part 21. The first surface 231 may form a predetermined angle with the base part 21, and an angle formed between the first surface 231 and the base part 21 may be referred to as the first angle a1. The second surface 232 may extend from the base part 21 such that the second surface 232 is connected to the first surface 231. The second surface 232 may extend at a predetermined angle with the base part 21. The second surface 232 may form a predetermined angle with the base part 21, and an angle formed between the second surface 232 and the base part 21 may be referred to as a second angle a2.

The first surface 231 and the second surface 232 may be connected to each other at a point spaced a predetermined distance from the base part 21 in the first direction, and thus a cross section of the irregularity 23 perpendicular to the longitudinal direction (second direction) may form a triangular shape together with the first surface 231, the second surface 232, and a boundary between the irregularity 23 and the base part 21, but the present disclosure is not limited thereto. For example, the first surface 231 and the second surface 232 may be formed as curved surfaces, and in this case, a connection shape between the first surface 231 and the second surface 232 may be rounded rather than bent at a predetermined angle.

The first surface 231 and the second surface 232 may have an asymmetric shape in the first direction. In other words, a measure of the first angle a1 formed between the first surface 231 and the base part 21 and a measure of the second angle a2 formed between the second surface 232 and the base part 21 may be different from each other. In detail, the measure of the first angle a1 may be greater than the measure of the second angle a2. In this case, the first surface 231 may be a surface positioned above the second surface 232 when the solar cell module is installed on an outer wall of the building or the like.

Preferably, the measure of the first angle a1 may be 60 degrees or more and 90 degrees or less. The measure of the first angle a1 may be, for example, 90 degrees (FIG. 4). Preferably, the measure of the second angle a2 may be 30 degrees or more and 70 degrees or less. For example, the measure of the first angle a1 may be 90 degrees, and the measure of the second angle a2 may be 45 degrees.

The plurality of irregularities 23 may be also continuously arranged in the third direction without being spaced apart from each other (FIGS. 4 and 5). In other words, the first surface 231 of one of the two adjacent irregularities 23 and the second surface 232 of the other one irregularity may be connected to each other, and thus the irregularities 23 may be arranged with no gap.

Unlike this, the plurality of irregularities 23 may be arranged to be spaced a predetermined distance from each other in the third direction (FIG. 6). In this case, a distance “d” by which the plurality of irregularities 23 are spaced apart from each other may be changed in consideration of, for example, the elevation angle of the sunlight “l” that changes depending on a region as needed.

The solar cell module according to the embodiment of the present disclosure may further include the coating layer 40. The coating layer 40 may be formed in the optical pattern part 22. The coating layer 40 may be formed on a surface of the irregularity 23 of the optical pattern part 22 to reduce reflectance of the irradiated sunlight “l.” The coating layer 40 may be made of a material having a smaller refractive index than a refractive index of a material constituting the cover plate 20. For example, the coating layer 40 may be formed of magnesium fluoride (MgF₂). As a configuration of the coating layer 40 that reduces reflection of the sunlight “l” is adopted, the quantity of light reflected and escaping from the solar cell module is reduced, and thus the quantity of light input onto the surface of the solar cell 10 may be increased. Further, the irregularities 23 may be protected from external environments such as a temperature, humidity, and a mechanical impact using the configuration of the coating layer 40, and self-cleaning may be performed according to the material of the coating layer 40.

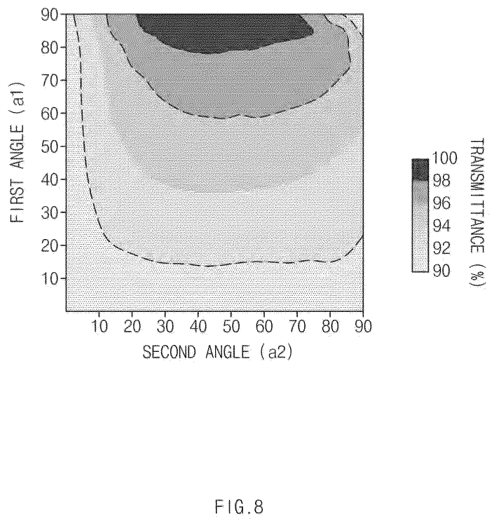

FIG. 8 is a graph depicting transmittance of the sunlight according to the first angle a1 and the second angle a2.

As the transmittance of the sunlight input to the solar cell module is increased, power generation performance of the module may be improved. Referring to FIG. 8, it may be identified that, when the measure of the first angle a1 is 60 degrees or more and 90 degrees or less and the measure of the second angle a2 is 30 degrees or more and 70 degrees or less, the transmittance of the sunlight is 96% or more. Thus, as described above, it is preferable that the measure of the first angle a1 be 60 degrees or more and 90 degrees or less and the measure of the second angle a2 be 30 degrees or more and 70 degrees or less.

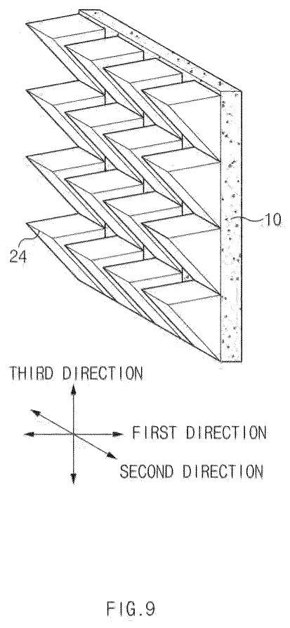

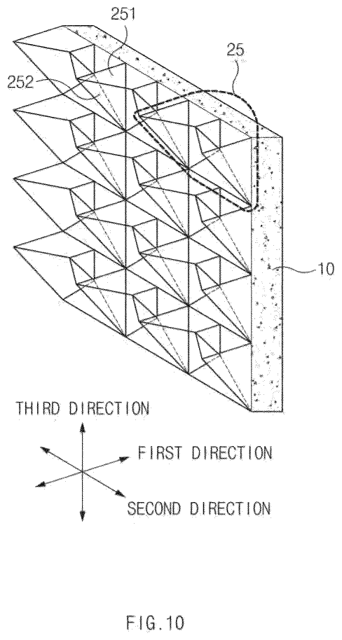

FIGS. 9 and 10 illustrate a solar cell module according to other embodiments of the present disclosure.

Another embodiment of the present disclosure may differ from the above embodiment in that the irregularities 23 are arranged continuously even in the second direction. It is noted that, except for the above difference, the contents of the solar cell module according to the embodiment of the present disclosure may be commonly applied even to the present embodiment. Thus, contents in common with the above embodiment are omitted as much as possible, and the present embodiment will be described while focused on the difference.

That is, in the solar cell modules according to another embodiment and still another embodiment of the present disclosure, the contents of the solar cell modules according to another embodiment and still another embodiment of the present disclosure except for what will be described below are replaced with the above-described contents of the solar cell module according to the embodiment of the present disclosure.

FIG. 9 is a perspective view illustrating a shape of a solar cell module according to another embodiment of the present disclosure. Referring to FIG. 9, irregularities 24 of the solar cell module according to another embodiment of the present disclosure may be continuously arranged in the second direction and the third direction. In this case, the plurality of irregularities 24 may be spaced a predetermined distance from each other in the second direction. In this case, a separation distance between the irregularities 24 in the second direction and/or the third direction is controlled according to the elevation angle of the sunlight or the like, and thus an area by which an optical path may be controlled may be efficiently adjusted.

FIG. 10 is a perspective view illustrating a shape of a solar cell module according to still another embodiment of the present disclosure. Referring to FIG. 10, irregularities 25 of the solar cell module according to still another embodiment of the present disclosure may be continuously arranged in the second direction and the third direction. In this case, a second surface 252 may have a shape recessed toward the cover plate 20. The second surface 252 may be recessed toward the cover plate 20 such that the irregularities 25 have a symmetrical shape with respect to an imaginary plane formed parallel to the first direction. In detail, the imaginary plane that serves as a standard for symmetry may be a plane formed parallel to the first direction and the third direction. In other words, a first surface 251 may have a symmetrical shape with respect to the plane formed parallel to the first direction and the third direction. Likewise, the second surface 252 connected to the first surface 251 may also have a symmetrical shape with respect to the plane formed parallel to the first direction and the third direction.

A solar cell module according to an embodiment of the present disclosure may increase efficiency of solar power generation by controlling an optical path of irradiated sunlight.

The solar cell module according to the embodiment of the present disclosure may reduce reflectance of the sunlight and improve an absorption rate of the sunlight.

In addition, the present disclosure includes effects that may be easily predicted by those skilled in the art from the configurations according to the embodiment of the present disclosure.

In the above description, the present disclosure has been described with the limited embodiments and drawings, but the above description is merely an illustrative description of the technical spirit of the present disclosure, and those skilled in the art to which the present disclosure pertains may derive various modifications and changes without departing from the essential features of the present disclosure.

Thus, the embodiments disclosed in the present disclosure are not intended to limit the technology spirit of the present disclosure, but are intended to describe the present disclosure, and the scope of the technical spirit of the present disclosure is not limited by these embodiments. The scope of protection of the present disclosure should be interpreted by the appended claims, and all technical spirits within the scope equivalent thereto should be interpreted as being included in the scope of the present disclosure.

What is claimed is:

1. A solar cell module comprising:
a solar cell configured to absorb sunlight; and
a cover plate configured to cover the solar cell,
wherein the cover plate comprises an optical pattern part comprising a plurality of irregularities having an asymmetrical shape with respect to a first direction perpendicular to the solar cell.

2. The solar cell module of claim 1, wherein the cover plate comprises a base part configured to cover the solar cell, the optical pattern part protrudes from the base part, and the base part and the optical pattern part are integrally formed.

3. The solar cell module of claim 2, wherein the solar cell is positioned on one surface of the base part, and the optical pattern part is formed on the other surface opposite to the one surface of the base part.

4. The solar cell module of claim 2, wherein each of the irregularities comprises a first surface extending from the base part and a second surface extending from the base part such that the second surface is connected to the first surface, and
wherein a measure of a first angle formed between the first surface and the base part and a measure of a second angle formed between the second surface of the base part are different from each other.

5. The solar cell module of claim 4, wherein the measure of the first angle is greater than the measure of the second angle.

6. The solar cell module of claim 4, wherein the first angle is about 60 degrees or more and 90 degrees or less, and the second angle is about 30 degrees or more and 70 degrees or less.

7. The solar cell module of claim 4, wherein each of the plurality of irregularities has a shape extending in a second direction perpendicular to the first direction.

8. The solar cell module of claim 7, wherein a cross section of the irregularities, which is perpendicular to the second direction, has a triangular shape.

9. The solar cell module of claim 7, wherein the plurality of irregularities are continuously arranged in a third direction intersecting the first direction and the second direction.

10. The solar cell module of claim 9, wherein the plurality of irregularities are spaced a predetermined distance from each other in the third direction.

11. The solar cell module of claim 9, wherein, among two adjacent irregularities, the first surface of one irregularity and the second surface of the other one irregularity are connected to each other.

12. The solar cell module of claim 9, wherein the plurality of irregularities are continuously arranged in the second direction and the third direction.

13. The solar cell module of claim 1, wherein the cover plate is formed of a glass material or a polymer material.

14. The solar cell module of claim 1, further comprising:
a coating layer provided in the irregularity to prevent reflection of the sunlight.

15. The solar cell module of claim 1, further comprising:
a glass plate stacked between the solar cell and the cover plate,
wherein the cover plate is formed of a polymer material.

16. The solar cell module of claim 4, wherein the second surface is recessed toward the cover plate.

17. The solar cell module of claim 16, wherein the irregularities have a symmetrical shape with respect to a plane formed parallel to the first direction.

18. A cover plate configured to cover a solar cell, wherein an optical pattern part having a plurality of irregularities having an asymmetrical shape with respect to a first direction perpendicular to an extension direction of the cover plate is formed.

19. A solar cell module comprising:
a solar cell; and
a cover plate configured to cover the solar cell,
wherein the cover plate comprises a plurality of irregularities having a triangular cross-sectional shape with asymmetrical angles,
wherein the irregularities are configured to reduce reflection of sunlight at high incident angles by directing sunlight toward the solar cell,
wherein a first angle of the triangular cross-section is greater than a second angle of the triangular cross-section, and
wherein the first angle of the triangular cross-section is between about 30° and 70° and the second angle is between about 60° and 90°.

20. The solar cell module of claim 19, wherein the irregularities are arranged such that first and second surfaces of adjacent irregularities are connected, forming a continuous pattern across a surface of the cover plate, and wherein a coating layer is applied on a surface of the irregularities, the coating layer having a refractive index lower than that of the material of the cover plate.
